(19) United States
(12) Patent Application Publication
(10) Pub. No.: US 2012/0032206 A1
(43) Pub. Date: Feb. 9, 2012

(54) VARIABLE HEIGHT LIGHT EMITTING DIODE AND METHOD OF MANUFACTURE

(76) Inventor: Byoung gu Cho, Seoul (KR)

(21) Appl. No.: 12/851,573

(22) Filed: Aug. 6, 2010

(51) Int. Cl. H01L 33/08; H01L 21/30

(52) U.S. Cl. 257/89; 438/35; 257/E33.055; 257/E21.211

(57) ABSTRACT

In general, embodiments of the present invention provide a variable height LED and method of manufacture. Specifically, under embodiments of the present invention, a buffer layer is applied (e.g., selectively) over a wafer, and a set of LED chips is provided over the buffer layer. One role of the buffer layer is to increase a height of at least a subset of the chips. As such, the buffer layer could be applied using any processing method now known or later developed. For example, the buffer layer could be selectively deposited, etched, etc. Regardless, in a typical embodiment, the buffer layer comprises a mesa structure having a thickness less than approximately 100 μm. In addition, the mesa structure is typically constructed from three RGB wafers.

### CROSS-REFERENCE TO RELATED INVENTION

The present invention is related in some aspects to commonly-owned and co-pending application Ser. No. 12/693,632, filed Jan. 26, 2010, and entitled LIGHT EMITTING DIODE (LED) AND METHOD OF MANUFACTURE, the entire contents of which are herein incorporated by reference. The present invention is also related in some aspects to commonly-owned and co-pending application Ser. No. 12/750,823, filed Mar. 31, 2010, and entitled MULTICHIP LIGHT EMITTING DIODE (LED) AND METHOD OF MANUFACTURE, the entire contents of which are herein incorporated by reference. The present invention is also related in some aspects to commonly owned and co-pending application Ser. No. 12/750,816, entitled “LIGHT EMITTING DIODE HAVING A WAVELENGTH SHIFT LAYER AND METHOD OF MANUFACTURE”, which was filed on Mar. 31, 2010, the entire contents of which are herein incorporated by reference.

### FIELD OF THE INVENTION

The present invention generally relates to Light Emitting Diodes (LEDs). Specifically, the present invention relates to the manufacture of a variable height LED using a buffer layer.

### BACKGROUND OF THE INVENTION

As LEDs continue to grow in popularity as an efficient technological approach, the need for continued advancement grows as well. Along these lines, obtaining white light output from LED is not only needed, but also difficult to achieve. Many approaches in the past have attempted to find new ways to obtain white light. However, many of these approaches perform such processing at the chip level instead of at the wafer level. Such an approach can result in chip waste. Moreover, none of the existing approaches vary phosphor ratios based on an underlying device measurement (such as a wavelength of a light output). For example, U.S. Pat. No. 6,650,044 forms a pedestal on top of a pad. The pedestal is a stud bump that is used for connectivity. This approach is not ideal as it is inefficient, does not provide chip level coating, is much harder to polish, and is easily contaminated. Moreover, in previous approaches such as U.S. Pat. No. 7,446,733 and 7,190,328, pads were manufactured so that all LEDs thereon had the same height. In view of the foregoing, there exists a need for an LED and associated method of manufacture that addresses the deficiencies of the related art.

### SUMMARY OF THE INVENTION

In general, embodiments of the present invention provide a variable height LED and method of manufacture. Specifically, under embodiments of the present invention, a buffer layer is applied (e.g., selectively) over a wafer, and a set of LED chips is provided over the buffer layer. One role of the buffer layer is to increase a height of at least a subset of the chips. As such, the buffer layer could be applied using any processing method now known or later developed. For example, the buffer layer could be selectively deposited, etched, etc. Regardless, in a typical embodiment, the buffer layer comprises a mesa structure having a thickness less than approximately 100 μm. In addition, the mesa structure is typically constructed from three RGB wafers.

A first aspect of the present invention provides a method for producing a wafer having Light Emitting Diodes (LEDs) of variable heights, comprising: providing a wafer; applying a buffer layer over the wafer; and providing a set of chips over the buffer layer, the buffer layer increasing a height of at least a subset of the set of chips.

A second aspect of the present invention provides a method for producing a wafer having Light Emitting Diodes (LEDs) of variable heights, comprising: providing a wafer; applying a buffer layer over the wafer, the buffer layer comprising a mesa structure having a thickness less than approximately 100 μm; and providing a set of LED chips over the buffer layer, the buffer layer increasing a height of at least a subset of the set of LED chips.

A third aspect of the present invention provides a Light Emitting Diode (LED) device, comprising: a wafer; a buffer layer applied over the wafer, the buffer layer comprising a mesa structure having a thickness less than approximately 100 μm; and a set of LED chips applied over the buffer layer, the buffer layer increasing a height of at least a subset of the set of LED chips.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts three RGB layers being used to construct a mesa structure that is used as a buffer layer/mask according to an embodiment of the present invention.

FIG. 2 depicts a method of applying a buffer layer to yield a variable height LED according to an embodiment of the present invention.

FIG. 3 depicts a plurality of interconnected LED chips with an underlying buffer layer/mask according to an embodiment of the present invention.

FIG. 4 depicts a graphic representation of a chip level conformal coating (CLCC) mode in the wafer level according to an embodiment of the present invention.

FIG. 5 depicts the plurality of interconnected LED chips according to an embodiment of the present invention.

FIG. 6 depicts a specific color scheme and interconnection of a plurality of LED chips after conversion of a light output by a target LED chip to white light according to an embodiment of the present invention.

The drawings are not necessarily to scale. The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

As indicated above, embodiments of the present invention provide a variable height LED and method of manufacture. Specifically, under embodiments of the present invention, a buffer layer is applied (e.g., selectively) over a wafer, and a set of LED chips is provided over the buffer layer. One role of the buffer layer is to increase a height of at least a subset of the chips. As such the buffer layer could be applied using any processing method now known or later developed. For example, the buffer layer could be selectively deposited, etched, etc. It is understood in advance that although a typical embodiment of the present invention corresponds to a varying the heights of LED chips, the teachings recited herein could be applied to any type of chip.

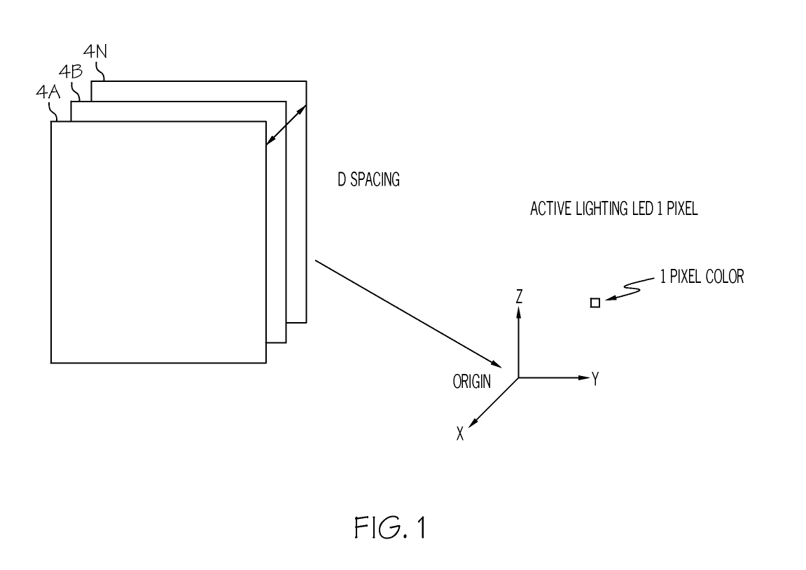

Regardless, in a typical embodiment, the buffer layer comprises a mesa structure having a thickness less than approximately 100 μm. In addition, the mesa structure is typically constructed from three RGB wafers. This embodiment is shown in FIG. 1. Specifically, FIG. 1 shows a mesa structure 2 comprising RGB wafers 4A-N. Each wafer 4A-N is separate by a predetermined distance D. In a typical embodiment, mesa structure has a thickness less than approximately 100 μm. A further shown in FIG. 1, a pixel 6 has R, G, and B components, each taking a constant length apart to the Z-axis (e.g., the fixed origin point. In accordance with the present invention, since a pixel has an RGB, all colors can be generated hereunder. Moreover, the Z-axis can provide variation for height. Along these lines, it is not necessary for the height of all LED chips to be uniformly varied. For example, LED chip alpha could have a height of A, LED chip beta could have a height of B, while LED gamma could have a height of C. Still yet, the teachings recited herein could be implemented in conjunction with any additional layers (e.g., a wavelength shift layer or WSL) such as those discussed in the above-incorporated applications.

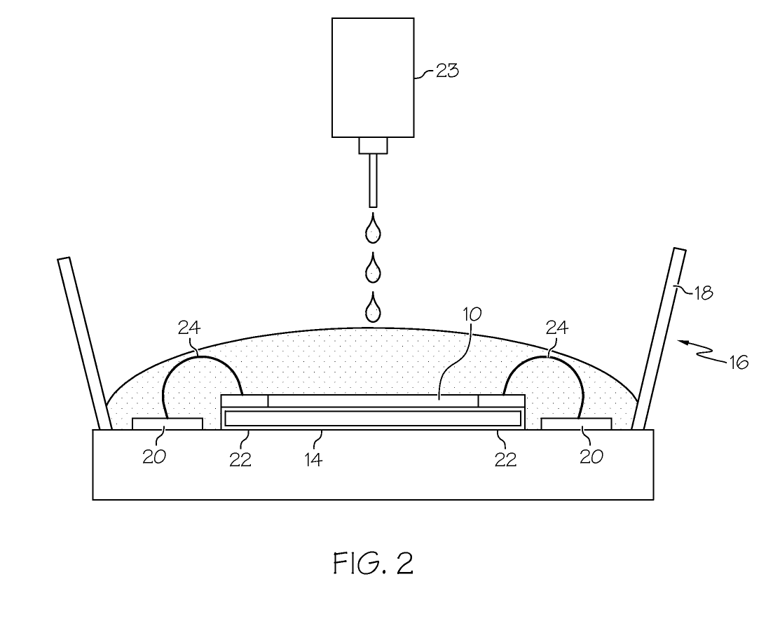

Referring now to FIG. 2, the application of buffer layer 14 is schematically shown. It is understood that dispenser 23 can be used to apply some or all of the layers provided hereunder. Specifically, dispenser 23 can be used to apply buffer layer 14 over a wafer. Thereafter, a set (at least one) of chips can be positioned over buffer layer 14. Along these lines, buffer layer 14 can be applied at various portions (e.g., selectively deposited along wafer), etched, etc. The buffer layer serves to vary the heights of at least a subset of the LED chips. In any event, as shown, there is lead frame 16 including cup 18 and the LED chip 10 is attached in the center of the cup, and the metal pad 20 and lead frame 22 are connected by the wire bond 24. Buffer layer 14 is applied using dispenser 23. Along these lines, it is understood that dispenser 23 can also be used to applied any of the layers (e.g., a wavelength shift layer or WSL) of any of the above-incorporated patent applications.

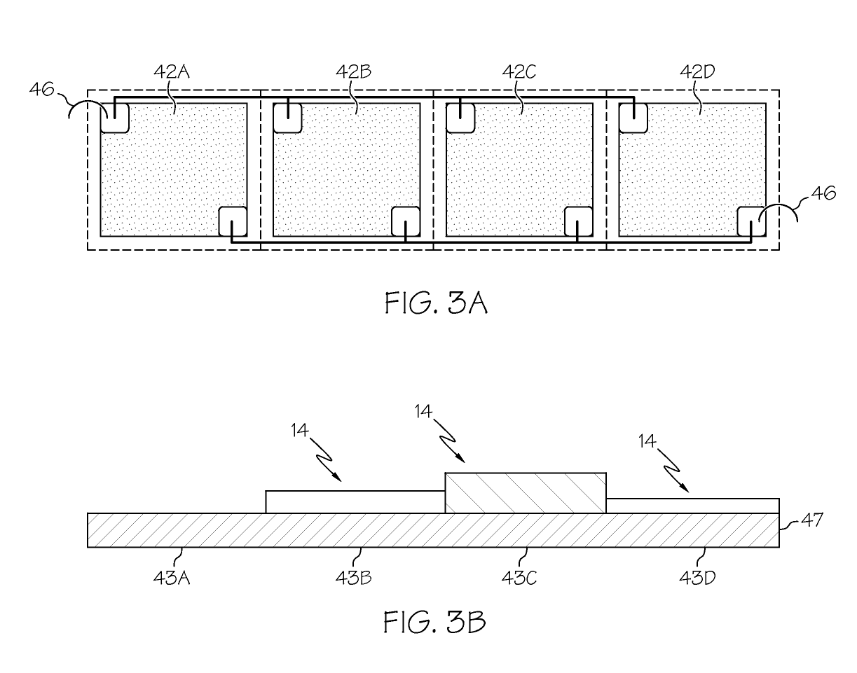

Referring to FIG. 3, an illustrative array/plurality of LED chips 40 is shown. As depicted, array 40 comprises chips 42A-D electrically interconnected via red metal lines 44. In addition, ground contacts 46 are used to connect array 40 to a ground. It should be understood in advance when the terms such as “red LED chip”, “blue LED chip”, “green LED chip” are used herein, what is meant is that the LED chips produce light having those colors (e.g., red light, blue light, green light, etc.). Thus, “red LED chip” is an abbreviated way of saying “red light producing LED chip”. As further shown, LED chips 42A-D will be positioned over buffer layer 14. Mentioned above, buffer layer need not have a constant thickness. Rather, wafer 47 has area 43A where no buffer layer 14 was applied and areas 43B-D where three different thicknesses of buffer layer 14 were applied. Such application of buffer layer 14 will result in LED chips 42A-D having varying heights.

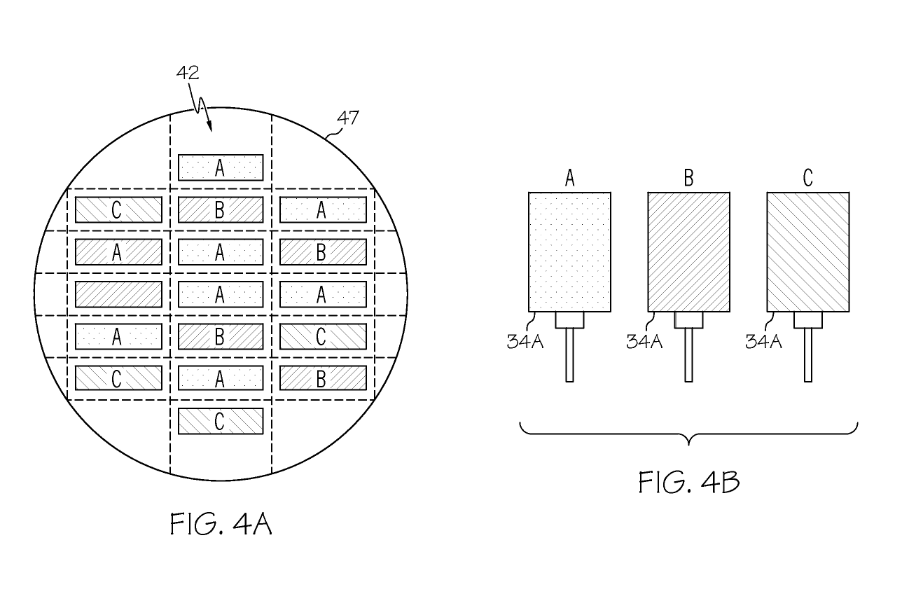

In FIG. 4, an additional feature of the present invention is schematically shown. In order to implement the target white color output coordinate in which it is identical about all chips 42 in wafer 47, a proper fluorescent substance combination ratio in which it has to be coated in each unit chip by using the result of measuring the wavelength of all chips 42 is determined. For example, the combination ratio of A in case of the wavelength a, the combination ratio of B in case of the wavelength β, and the combination ratio of C in case of the wavelength γ is applied. Dispensers 34A-C correspond to the multiple combination ratio and three coating materials are prepared. Each dispenser 34A-C is filled with the fluorescent substance of the respectively different combination ratio A, B, or C.

As seen in FIG. 4, dispenser 34A-C makes the coated film (fluorescent substance plus silicon material) in which it corresponds to each unit chip while at the wafer level by the dispensing method. Therefore, it is comprised of the fluorescent substance conformal coating in the adhesion layer that was previously applied to the top surface of each LED chip. In this way, the white LED chip is ultimately implemented in the wafer level through the fluorescent substance coating. Under the present invention, three examples in which it independently coats the fluorescent substance plus silicon material in the wafer level according to each unit chip 30 are proposed.

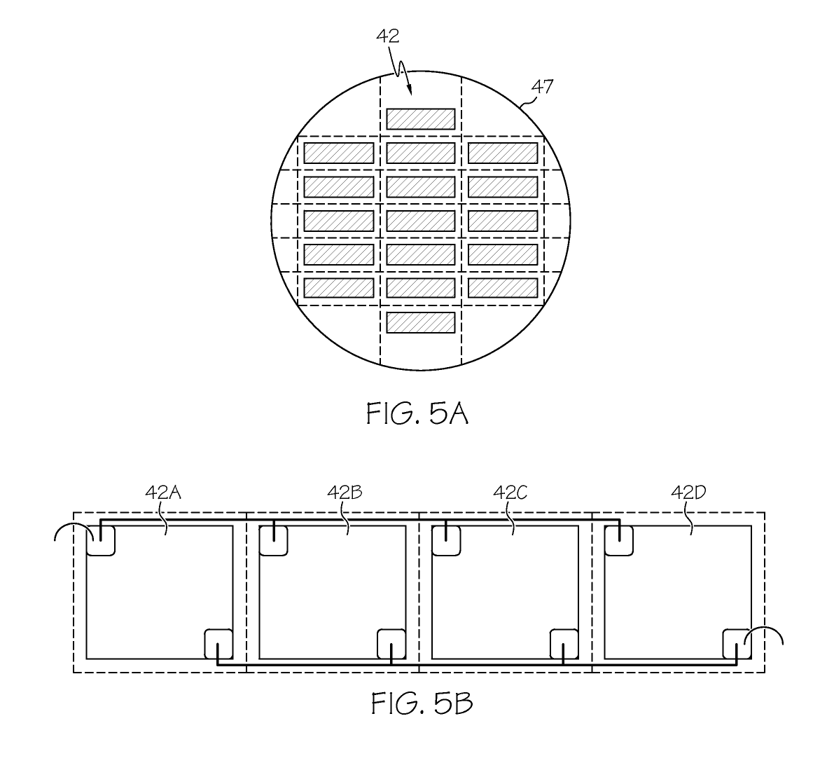

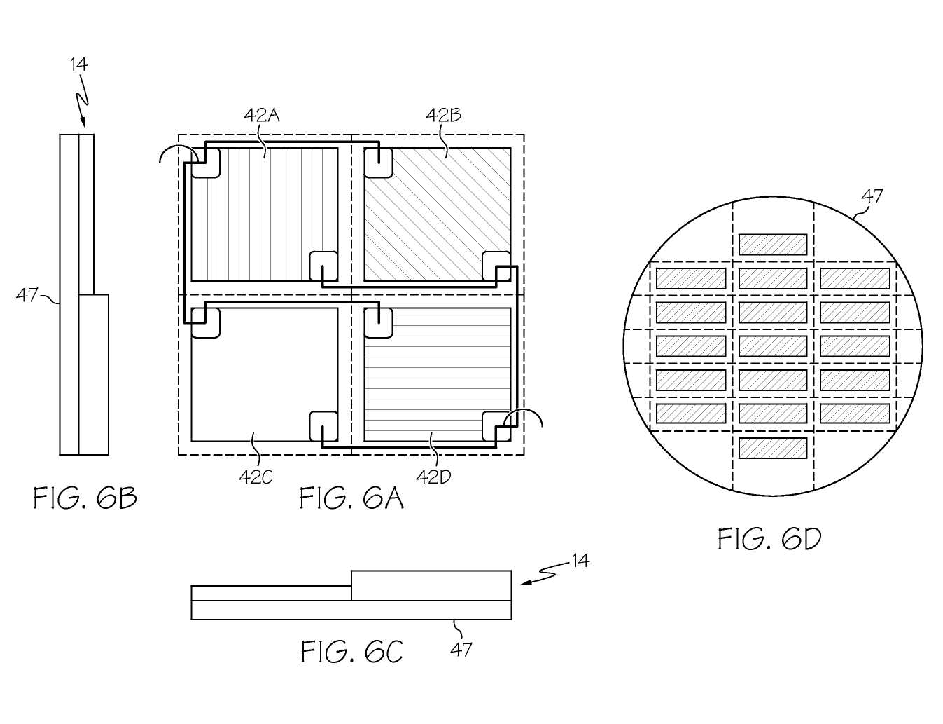

Regardless, referring now to FIG. 5, an illustrative embodiment according to the present invention is shown. As depicted, array of chips 42A-D is drawn from chips of wafer 47. In a typical embodiment, array of chips 42A-D comprise four chips 42A-D: a red LED chip 42A, a green LED chip 42B, a blue LED chip 42C, and a target LED chip 42D. Referring to FIG. 6, this process will be described in greater detail. As depicted, red LED chip 42A, green LED chip 42B, blue LED chip 42C, and target LED chip 42D are electrically interconnected in a 2×2 matrix format. Under the present invention, chips 42A-D will have varying heights due to the underlying buffer layer 14. Prior to or after their interconnection, LED chips 42A-D are coated with the conformal coating as previously described. Specifically, a wavelength of light output of one or more LED chips 42A-D is measured. Based on this measurement, a conformal coating is applied to one or more of LED chips 42A-D. As described above in conjunction with FIGS. 1-4, a certain wavelength will result in the application of a conformal coating having a corresponding phosphor ratio (e.g., comprised of yellow, green and/or red). Moreover, the conformal coating can be applied to any or all LED chips 42A-D using any of the isolation techniques discussed herein. Illustrative techniques for isolating the area to which the conformal coating is applied include (among others): (1) using a paraffin wax; (2) using a silk screen; and (3) using a photo resist. Using the conformal coating, the light output by target LED chip 42D will be converted to white light.

The foregoing description of various aspects of the invention has been presented for purposes of illustration and description. It is not intended to be exhaustive or to limit the invention to the precise form disclosed and, obviously, many modifications and variations are possible. Such modifications and variations that may be apparent to a person skilled in the art are intended to be included within the scope of the invention as defined by the accompanying claims.

What is claim is:

1. A method for producing a wafer having Light Emitting Diodes (LEDs) of variable heights, comprising:
providing a wafer;
applying a buffer layer over the wafer; and
providing a set of chips over the buffer layer, the buffer layer increasing a height of at least a subset of the set of chips.

2. The method of claim 1, the set of chips being LED chips and the buffer layer being selectively applied beneath predetermined LED chips.

3. The method of claim 1, the buffer layer comprising a mesa structure having a thickness less than approximately 100 μm.

4. The method of claim, 3, the mesa structure comprising a plurality of RGB wafers.

5. The method of claim 4, the plurality of RGB wafers each being separated from one another by a predetermined distance.

6. The method of claim 1, the set of chips being implemented in an RGB device.

7. A method for producing a wafer having Light Emitting Diodes (LEDs) of variable heights, comprising:
providing a wafer;
applying a buffer layer over the wafer, the buffer layer comprising a mesa structure having a thickness less than approximately 100 μm; and
providing a set of LED chips over the buffer layer, the buffer layer increasing a height of at least a subset of the set of LED chips.

8. The method of claim 7, the buffer layer being selectively applied beneath predetermined LED chips.

9. The method of claim 7, the mesa structure comprising a plurality of RGB wafers.

10. The method of claim 9, the plurality of RGB wafers each being separated from one another by a predetermined distance.

11. The method of claim 7, the set of LED chips being implemented in an RGB device.

12. A Light Emitting Diode (LED) device, comprising:
a wafer;
a buffer layer applied over the wafer, the buffer layer comprising a mesa structure having a thickness less than approximately 100 μm; and
a set of LED chips applied over the buffer layer, the buffer layer increasing a height of at least a subset of the set of LED chips.

13. The LED device of claim 12, the buffer layer being selectively applied beneath predetermined LED chips.

14. The LED device of claim 12, the mesa structure comprising a plurality of RGB wafers.

15. The LED device of claim 14, the plurality of RGB wafers each being separated from one another by a predetermined distance.

16. The LED device of claim 12, the set of LED chips being implemented in an RGB device.
